(19) United States
(12) Patent Application Publication
(10) Pub. No.: US 2013/0236997 A1
(43) Pub. Date: Sep. 12, 2013

(54) METHOD OF FABRICATING LIGHT EMITTING DEVICE

(71) Applicant: SAMSUNG ELECTRONICS CO., LTD., Suwon-si (KR)

(72) Inventors: Sang Hyun LEE, Suwon (KR); Gam Han YONG, Suwon (KR); Seong Deok HWANG, Seoul (KR)

(73) Assignee: SAMSUNG ELECTRONICS CO., LTD., Suwon-si (KR)

(21) Appl. No.: 13/791,057

(22) Filed: Mar. 8, 2013

(30) Foreign Application Priority Data
Mar. 8, 2012 (KR) 10-2012-0023817

(51) Int. Cl. H01L 33/48

(52) U.S. Cl. CPC H01L 33/48
USPC 438/27; 438/28

(57) ABSTRACT

A light emitting device and a method for fabricating the same are provided. The method includes: forming a plurality of light emitting laminates in which a first conductivity-type semiconductor layer, an active layer, and a second conductivity-type semiconductor layer are sequentially laminated on a growth substrate; mounting the growth substrate on a substrate including a plurality of terminal units each including a pair of electrode terminals; electrically connecting the second conductivity-type semiconductor layer of each of the light emitting laminates to a first electrode terminal of a corresponding terminal unit; removing the growth substrate to expose the first conductivity-type semiconductor layer; forming an insulating layer on a lateral surface of each of the plurality of light emitting laminates; and electrically connecting the exposed first conductivity-type semiconductor layer of each of the light emitting laminates to a second electrode terminal of the corresponding terminal unit.

### CROSS-REFERENCE TO RELATED APPLICATION

This application claims priority from Korean Patent Application No. 10-2012-0023817, filed on Mar. 8, 2012 in the Korean Intellectual Property Office, the disclosure of which is incorporated herein by reference in its entirety.

### BACKGROUND

1. Field

Exemplary embodiments relate to a light emitting device and a method of fabricating a light emitting device.

2. Description of the Related Art

A light emitting diode (LED), commonly utilized in simple small home appliances and the field of special interiors, has been applied to multiple applications and various usage environments including a backlight unit (BLU) for a display, a general illumination device, and an electric device, and efforts of enhancing LED efficiency have continued to be made.

Also, demand for a degree of freedom in designing products employing an LED is increasing. For example, the width of a BLU continues to be reduced to allow, for example, an LED TV to be thinner, and the size of LED products is demanded to be reduced in order to implement various forms of illumination devices or electrical devices.

A related art general LED package is fabricated such that an LED layer as a lamination structure of a semiconductor layer is grown on a growth substrate, the LED layer is transferred to a new support substrate, and then, an LED chip formed by removing the growth substrate is assembled on a package substrate.

Thus, in order to manufacture a final product, a separate support substrate is to be prepared and the LED layers are to be bonded to the support substrate, making the overall fabrication process complicated and degrading productivity.

Also, since an additional component such as the support substrate is used, production costs may be increased according to the increase in the number of components, and it is not easy to make the product thinner due to the size of the support substrate.

### SUMMARY

One or more exemplary embodiments provide a method of fabricating a light emitting device having a reduced number of components by omitting a support substrate in fabricating a light emitting device such as a light emitting diode (LED) package, and simplifying the overall process thereof.

According to an aspect of an exemplary embodiment, there is provided a method for fabricating a light emitting device, the method including: forming a plurality of light emitting laminates in which a first conductivity-type semiconductor layer, an active layer, and a second conductivity-type semiconductor layer are sequentially laminated on a growth substrate; mounting the growth substrate on a substrate including a plurality of terminal units each including a pair of electrode terminals, such that the plurality of light emitting laminates respectively face the plurality of terminal units in a corresponding manner; joining and electrically connecting the second conductivity-type semiconductor layer of each of the plurality of light emitting laminates to a first electrode terminal, among the pair of electrode terminals, of a corresponding terminal unit; removing the growth substrate such that the first conductivity-type semiconductor layer of each of the plurality of light emitting laminates is exposed; forming an insulating layer on a lateral surface of each of the plurality of light emitting laminates; and electrically connecting the exposed first conductivity-type semiconductor layer of each of the plurality of light emitting laminates to a second electrode terminal, among the pair of electrode terminals, of the corresponding terminal unit.

The forming of the light emitting laminates may include: sequentially growing the first conductivity-type semiconductor layer, the active layer, and the second conductivity-type semiconductor layer on the growth substrate; and removing portions of the grown first conductivity-type semiconductor layer, the grown active layer, and the grown second conductivity-type semiconductor layer other than portions forming the plurality of light emitting laminates.

An electroconductive adhesive may be provided on the second conductivity-type semiconductor layer of each of the plurality of light emitting laminates to join the plurality of light emitting laminates and the plurality of terminal units in the corresponding manner.

The substrate may further include a recess which accommodates a light emitting laminate.

At least portions of the pair of electrode terminals of the terminal unit may be within the recess.

The second conductivity-type semiconductor layer may be joined to the first electrode terminal within the recess.

The method may further include modifying a surface of the first conductivity-type semiconductor layer after the removing of the growth substrate.

The method may further include forming a current spreading layer on the exposed first conductivity-type semiconductor layer after the removing of the growth substrate.

The method may further include forming a wavelength conversion layer on the substrate to cover a light emitting laminate.

The method may further include forming a molded unit on the substrate to cover a light emitting laminate.

The method may further include cutting to separate the plurality of light emitting laminates.

According to an aspect of another exemplary embodiment, there is provided a method for fabricating a light emitting device, the method including: forming a plurality of light emitting laminates in which a first conductivity-type semiconductor layer, an active layer, and a second conductivity-type semiconductor layer are sequentially laminated on a growth substrate; removing portions of the second conductivity-type semiconductor layer and the active layer from the plurality of light emitting laminates to expose portions of the first conductivity-type semiconductor layer; mounting the growth substrate on a substrate including a plurality of terminal units each including a pair of electrode terminals, such that the plurality of light emitting laminates respectively face the plurality of terminal units in a corresponding manner; joining and electrically connecting the second conductivity-type semiconductor layer of each of the plurality of light emitting laminates to a first electrode terminal, among the pair of electrode terminals, of a corresponding terminal unit among the plurality of terminal units, and joining and electrically connecting the first conductivity-type semiconductor layer of each of the plurality of light emitting laminates to a second electrode terminal, among the pair of electrode terminals, of the corresponding terminal unit; and removing the growth substrate such that the first conductivity-type semiconductor layer of each of the plurality of light emitting laminates is exposed.

The forming the light emitting laminates may include: sequentially growing the first conductivity-type semiconductor layer, the active layer, and the second conductivity-type semiconductor layer on the growth substrate; and removing portions of the grown first conductivity-type semiconductor layer, the grown active layer, and the grown second conductivity-type semiconductor layer other than portions forming the plurality of light emitting laminates.

An electroconductive adhesive may be provided on the second conductivity-type semiconductor layer and the exposed first conductivity-type semiconductor layer of each of the plurality of light emitting laminates to join the plurality of light emitting laminates and the plurality of terminal units in the corresponding manner.

The substrate may further include: a recess which accommodates a light emitting laminate.

At least portions of the pair of electrode terminals may be within the recess.

The second conductivity-type semiconductor layer may be joined to the first electrode terminal within the recess and the exposed first conductivity-type semiconductor layer may be joined to the second electrode terminal within the recess by the electroconductive adhesive.

The method may further include modifying a surface of the first conductivity-type semiconductor layer after the removing of the growth substrate.

The method may further include forming a current spreading layer on the exposed first conductivity-type semiconductor layer after the removing of the growth substrate.

The method may further include forming a wavelength conversion layer on the substrate to cover a light emitting laminate.

The method may further include forming a molded unit on the substrate to cover a light emitting laminate.

The method may further include cutting to separate the plurality of light emitting laminates.

According to an aspect of another exemplary embodiment, there is provided a method for fabricating a light emitting device, the method including: mounting a growth substrate on a substrate including a plurality of terminal units each including a pair of electrode terminals, such that a plurality of light emitting laminates on the growth substrate respectively face the plurality of terminal units in a corresponding manner, the plurality of light emitting laminates including a first conductivity-type semiconductor layer, an active layer, and a second conductivity-type semiconductor layer that are sequentially laminated on a growth substrate; joining and electrically connecting the second conductivity-type semiconductor layer of each of the plurality of light emitting laminates to a first electrode terminal, among the pair of electrode terminals, of a corresponding terminal unit among the plurality of terminal units; removing the growth substrate such that the first conductivity-type semiconductor layer of each of the plurality of light emitting laminates is exposed; and electrically connecting the exposed first conductivity-type semiconductor layer of each of the plurality of light emitting laminates to a second electrode terminal, among the pair of electrode terminals, of the corresponding terminal unit.

### BRIEF DESCRIPTION OF THE DRAWINGS

The above and other aspects, features and other advantages will be more clearly understood from the following detailed description taken in conjunction with the accompanying drawings, in which:

FIGS. 1 through 3 and 4A, 5A, 6A, 7A, 8A, 9A, 10A, 11A, 12A, and 13A are views schematically illustrating respective steps of a method of fabricating a light emitting device according to an exemplary embodiment;

FIGS. 4B, 5B, 6B, 7B, 8B, 9B, 10B, 11B, 12B, and 13B are views schematically illustrating respective steps of a method of fabricating a light emitting device according to another exemplary embodiment;

FIG. 14A is a view schematically showing a light emitting device fabricated through the method of fabricating a light emitting device according to an exemplary embodiment;

FIG. 14B is a view schematically showing a light emitting device fabricated through the method of fabricating a light emitting device according to another exemplary embodiment;

FIGS. 15A and 15B are views schematically showing a modification of a light emitting device fabricated according to an exemplary embodiment;

FIG. 16 is a view schematically showing another modification of a light emitting device fabricated according to an exemplary embodiment;

FIGS. 17 through 20 are views schematically illustrating respective steps of a method of fabricating a light emitting device according to another exemplary embodiment; and

FIG. 21 is a view schematically showing a light emitting device fabricated through a method of fabricating a light emitting device according to another exemplary embodiment.

### DETAILED DESCRIPTION OF EXEMPLARY EMBODIMENTS

Exemplary embodiments will now be described in detail referring to the accompanying drawings.

Exemplary embodiments may, however, be embodied in many different forms and should not be construed as being limited to the exemplary embodiments set forth herein.

Rather, these exemplary embodiments are provided so that this disclosure will be thorough and complete, and will fully convey the scope of the inventive concept to those skilled in the art.

In the drawings, the shapes and dimensions of elements may be exaggerated for clarity, and the same reference numerals will be used throughout to designate the same or like components.

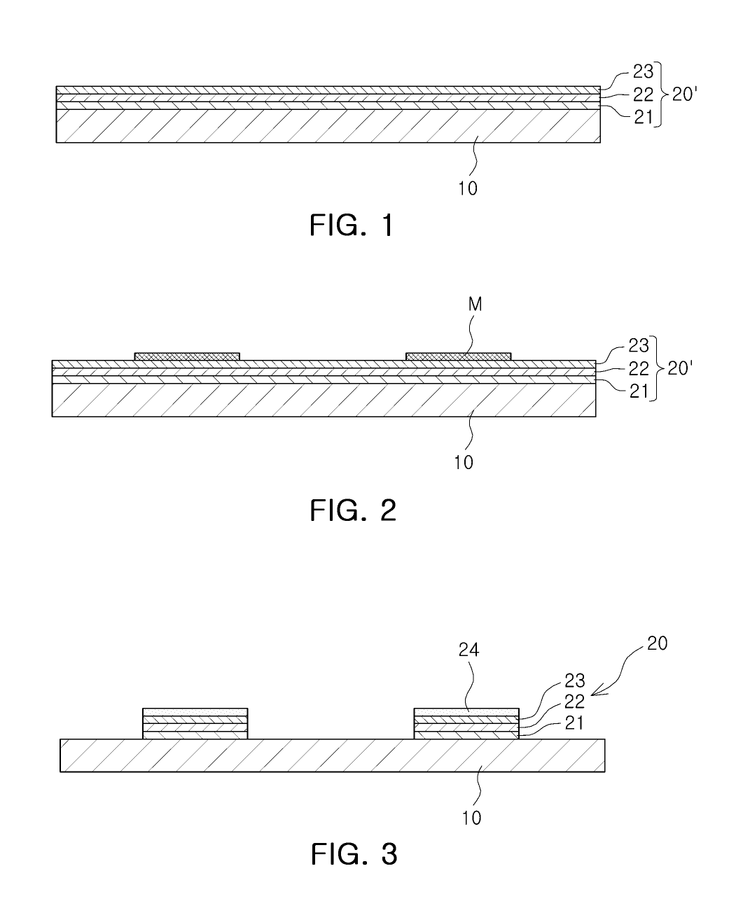

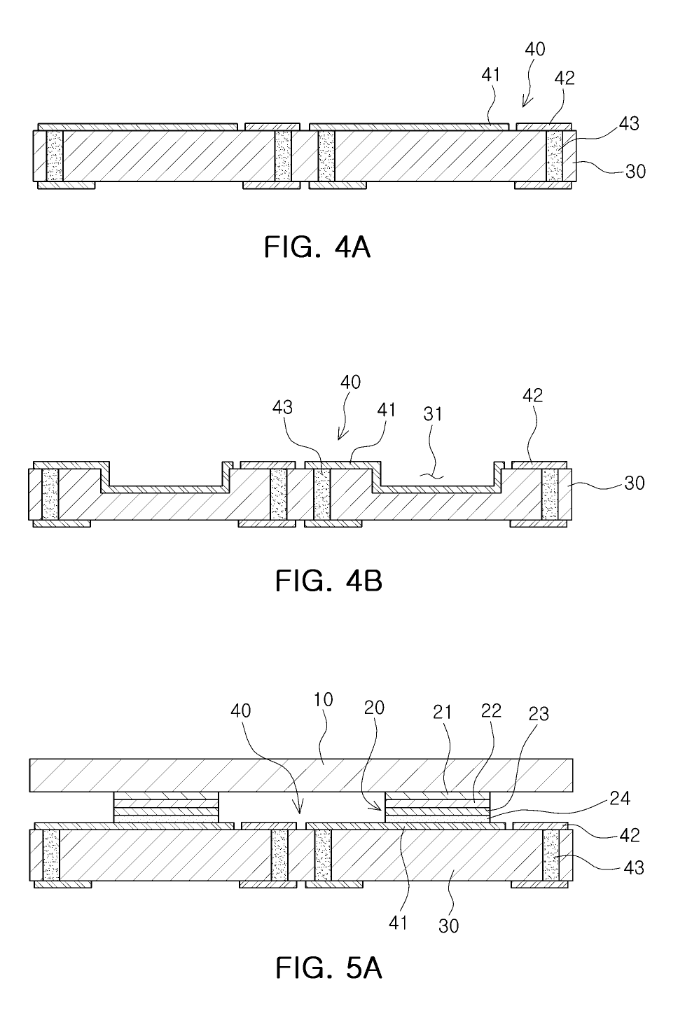

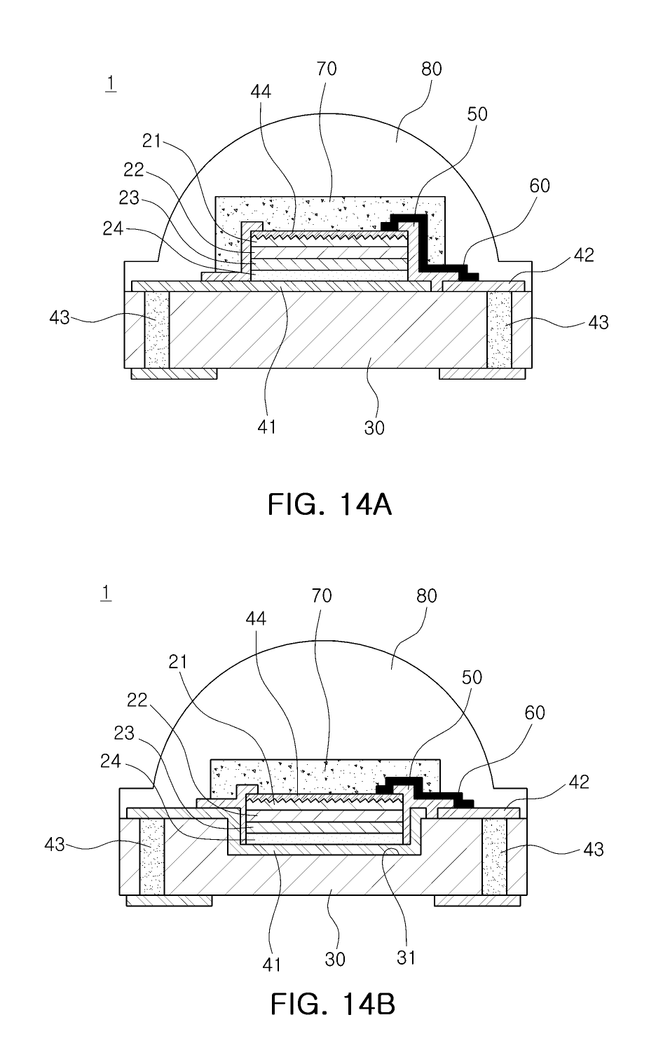

A method of fabricating a light emitting device according to an exemplary embodiment will be described with reference to FIGS. 1 through 13B. FIGS. 1 through 3 and 4A, 5A, 6A, 7A, 8A, 9A, 10A, 11A, 12A, and 13A are views schematically illustrating respective steps of a method of fabricating a light emitting device according to an exemplary embodiment, and FIGS. 1 through 3 and 4B, 5B, 6B, 7B, 8B, 9B, 10B, 11B, 12B, and 13B are views schematically illustrating respective steps of a method of fabricating a light emitting device according to a modification of FIGS. 4A to 13A. FIG. 14A is a view schematically showing a light emitting device fabricated through the method of fabricating a light emitting device according to the foregoing exemplary embodiment, and FIG. 14B is a view schematically showing a light emitting device fabricated through the method of fabricating a light emitting device according to the foregoing modification.

First, as illustrated in FIG. 1, a first conductivity-type semiconductor layer 21, an active layer 22, and a second conductivity-type semiconductor layer 23 are sequentially grown on a growth substrate 10 to form an LED layer 20′. The LED layer 20′ is a type of semiconductor layer that is, for example, deposited and grown on the growth substrate 10 through a chemical vapor deposition device, or the like.

As the growth substrate 10, a sapphire substrate, a SiC substrate, or the like, may be used, and various other types of substrate may also be used.

The first conductivity-type semiconductor layer 21 and the second conductivity-type semiconductor layer 23 may be an n-type semiconductor layer and a p-type semiconductor layer, respectively, and may be made of a nitride semiconductor. Thus, in the present exemplary embodiment, the first and second conductivity-types may be understood to indicate n-type and p-type conductivities, respectively, but one or more other exemplary embodiments are not limited thereto.

The active layer 22 is a layer for emitting light according to electron-hole recombination. The active layer 22 may have a multi-quantum well (MQW) structure formed by alternatively disposing InGaN layers as quantum well layers and (Al)GaN layers as quantum barrier layers. A blue LED may use an MQW structure including InGaN/GaN, or the like, and an ultraviolet (UV) LED may use an MQW structure including GaN/AlGaN, InAlGaN/InAlGaN, InGaN/AlGaN, or the like. In order to enhance efficiency of the active layer 22, a wavelength of light is adjusted by changing a composition ratio of indium (In) or aluminum (Al), or internal quantum efficiency is enhanced by changing the depth of the quantum well layer in the active layer 22, the number of active layers, the thickness of the active layer, or the like.

Like the first conductivity-type semiconductor layer 21, the second conductivity-type semiconductor layer 23 may also be made of a semiconductor material doped with a p-type impurity having an empirical formula AlₓIn_{y}Ga_{(1-x-y)}N (here, 0≦x≦1, 0≦y≦1, 0≦x+y≦1), and such materials may include GaN, AlGaN, and InGaN. Impurities used for doping the second conductivity-type semiconductor layer 23 may include magnesium (Mg), zinc (Zn), beryllium (Be), and the like.

Next, as illustrated in FIG. 2, a mask (M) is placed on the second conductivity-type semiconductor layer 23 and an etching process is performed thereon to remove portions other than the portion on which the mask (M) is placed. Accordingly, a plurality of light emitting laminates 20 (i.e., a plurality of light emitting lamination bodies) in which the first conductivity-type semiconductor layer 21, the active layer 22, and the second conductivity-type semiconductor layer 23 are sequentially laminated are formed on the growth substrate 10.

The plurality of light emitting laminates 20 may be spaced apart from one another and arranged in row and column directions. In the drawing, it is illustrated that two light emitting laminates 20 are provided, although it is understood that one or more other exemplary embodiments are not limited thereto and the number of light emitting laminates 20 may vary.

An adhesive 24 may be provided on the light emitting laminates 20. The light emitting laminates 20 may be joined to a substrate 30 of a package body by the adhesive 24 at a later time.

Then, as illustrated in FIG. 4A, the substrate 30 on which a plurality of terminal units 40 including a pair of first and second electrode terminals 41 and 42 are formed is provided. The substrate 30 may correspond to a package body in a general light emitting device package.

The substrate 30 may be made of a ceramic material such as MN, Al₂O₃, or the like, and the terminal units 40 may be formed (i.e., provided) on upper and lower surfaces of the substrate 30 and electrically connected through a conductive via 43 penetrating the substrate 30. In detail, the electrode terminals 41 and 42 formed on the upper surface of the substrate 30 may be electrically connected to the light emitting laminate 20, and the electrode terminals 41 and 42 formed on the lower surface of the substrate 30 may be electrically connected to a circuit board such as an illumination device on which a light emitting device is to be mounted afterwards.

In the present exemplary embodiment, the substrate 30 is made of a ceramic material and includes the terminal units 40 on upper and lower surfaces thereof and a conductive via 43 penetrating the substrate 30, although it is understood that one or more other exemplary embodiments are not limited thereto. The substrate 30 may be a printed circuit board (PCB), may be made of an organic resin material containing epoxy, triazine, silicon, polyimide, or the like, and any other organic resin materials, or a metal and a metal compound, and may include a metal PCB, a metal-core printed circuit board (MCPCB), or the like.

Meanwhile, as illustrated in FIG. 4B, the substrate 30 according to another exemplary embodiment may further include a recess 31 accommodating the light emitting laminate 20. A plurality of recesses 31 corresponding to the number of light emitting laminates 20 may be formed (i.e., provided) and are arranged to correspond to respective positions of the light emitting laminates 20. The recess 31 may be formed to have a size larger than a sectional area of the light emitting laminate 20 and may be formed upon a depression in the upper surface of the substrate 30 being made, such that the recess 31 has a depth less than the thickness (or height) of the light emitting laminate 20.

When the recess 31 is formed on the substrate 30, at least a portion of a pair of electrode terminals of the terminal unit 40 may be formed within the recess 31. For example, the first electrode terminal 41 may be formed on the upper surface of the substrate 30 and within the recess 31, while the second electrode terminal 42 may be formed to be separated from the first electrode terminal 41 on the substrate 30.

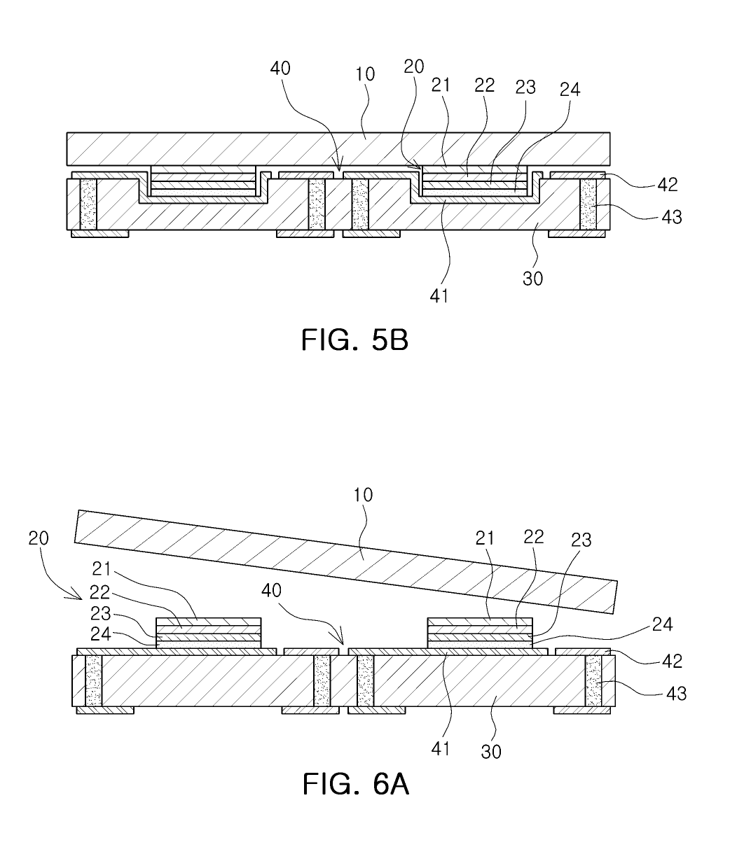

Then, as illustrated in FIG. 5A, the growth substrate 10 is reversed to be placed on the substrate 30 such that the respective light emitting laminates 20 face corresponding respective terminals 40, and the second conductivity-type semiconductor layer 23 of each of the light emitting laminates 20 is joined and electrically connected to any one of electrode terminals 41 of the corresponding terminal unit 40. For example, the plurality of the light emitting laminates 20 may be joined to the first electrode terminals 41 of the respective terminal units 40.

The light emitting laminate 20 may be joined and electrically connected to the first electrode terminal 41 through an electroconductive adhesive 24 provided on the second conductivity-type semiconductor layer 23. The conductive adhesive 24 may be made of an electrically conductive material. The light emitting laminate 20 and the electrode terminal 41 may be bonded through eutectic bonding, paste bonding, or the like.

Meanwhile, as illustrated in FIG. 5B, when the recesses 31 are formed on the substrate 30, the growth substrate 10 is reversed and mounted on the substrate 30 such that the respective light emitting laminates 20 are insertedly accommodated in the recesses 31, and the second conductivity-type semiconductor layers 23 of the respective light emitting laminates 20 are joined and electrically connected to the first electrode terminals 41 of the terminal unit 40 formed within the recess 31 by the electroconductive adhesives 24.

In this manner, when the light emitting laminate 20 is insertedly accommodated in the recess 31 of the substrate 30, the lateral surface of the light emitting laminate 20 is not in contact with an inner surface of the recess 31. Namely, a bottom surface corresponding to a location of the adhesive 24 (based on the drawing) of the light emitting laminate 20 is in contact with a bottom surface of the recess 31 through the adhesive 24, while the lateral surface, i.e., the surface perpendicular to the bottom surface, of the light emitting laminate 20 is not in contact with the recess 31. Thus, a problem in which the first conductivity-type semiconductor layer 21 is in contact with the first electrode terminal 41 formed on the inner surface of the recess 31 to thereby cause an electrical short, or the like, can be prevented.

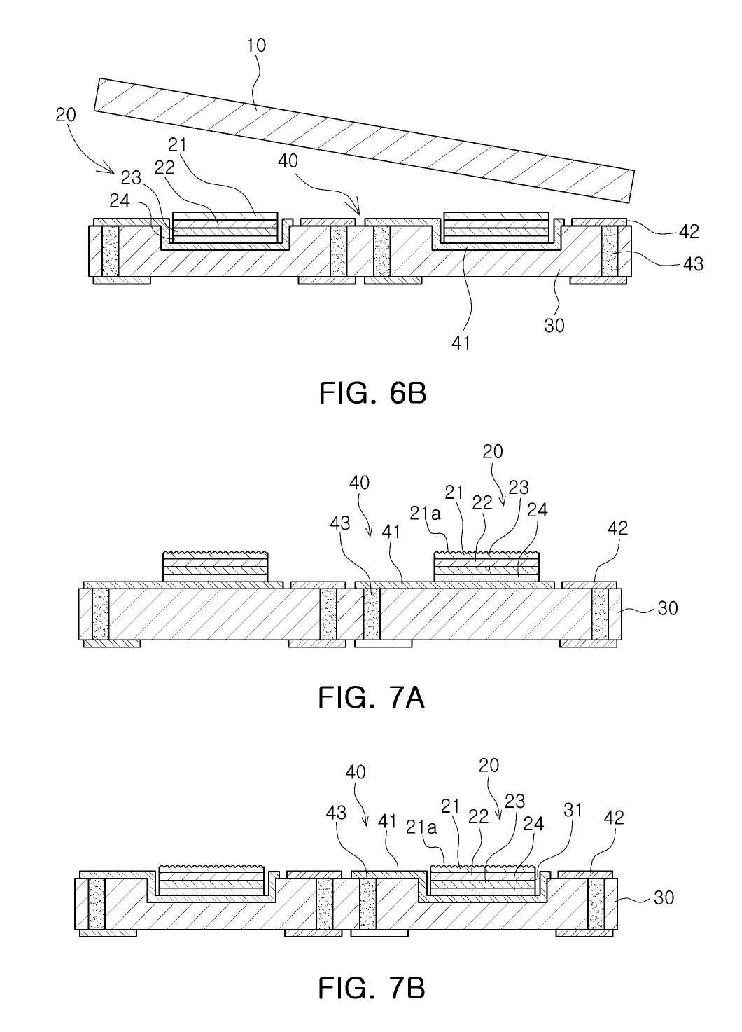

Thereafter, as illustrated in FIGS. 6A and 6B, the growth substrate 10 is removed such that the first conductivity-type semiconductor layers 21 of the plurality of light emitting laminates 20 are exposed. The growth substrate 10 may be removed through a laser lift-off process of irradiating a laser onto an interface thereof with the light emitting laminates 20. Alternatively, the growth substrate 10 may also be removed through a chemical process such as etching, or the like, or physically removed through grinding. However, the method of removing the growth substrate 10 is not limited to the foregoing methods and the growth substrate 10 may be removed according to various other methods.

Thereafter, as illustrated in FIGS. 7A and 7B, a process for enhancing light extraction efficiency, such as a surface modification, or the like, may be performed on a surface 21a of the first conductivity-type semiconductor layer 21 exposed after the removal of the growth substrate 10.

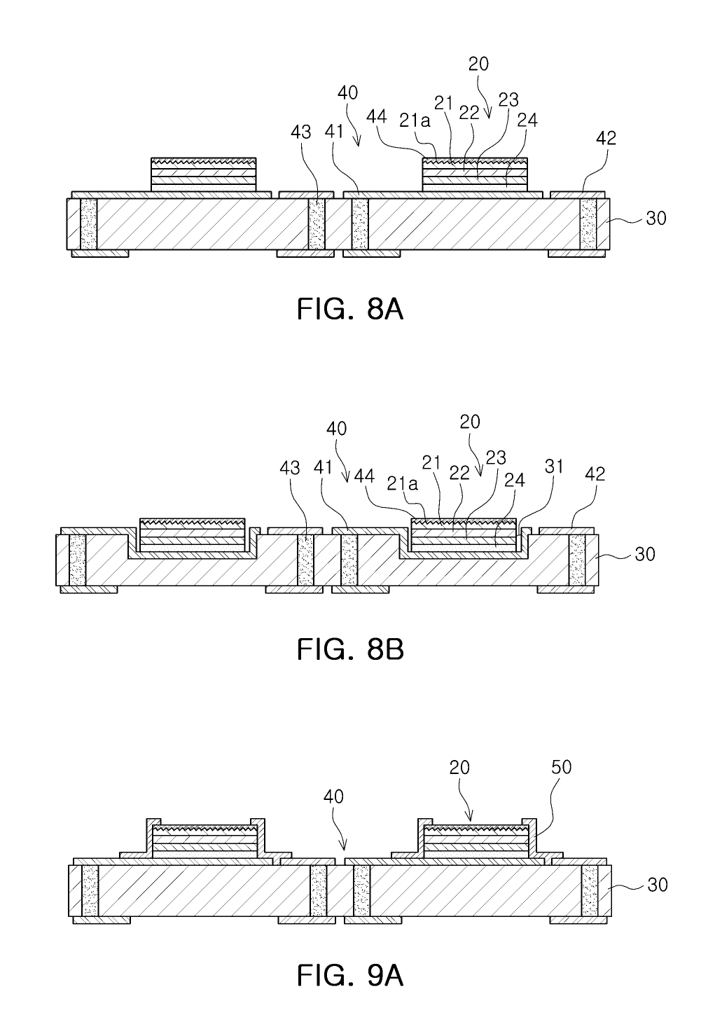

Also, as illustrated in FIGS. 8A and 8B, a process of forming (i.e., providing) a current spreading layer 44 may be performed to spread a current on the first conductivity-type semiconductor layer 21 exposed after the removal of the growth substrate 10. The current spreading layer 44 may be directly formed on the first conductivity-type semiconductor layer 21 or may be formed after the surface 21a is modified as illustrated in the drawing. The current spreading layer 44 may be made of a transparent conductive material, or may be made of an opaque conductive material according to circumstances. The current spreading layer 44 may be formed on the entire surface of the first conductivity-type semiconductor layer 21 or only on a portion of the first conductivity-type semiconductor layer 21.

The surface modifying process and the current spreading layer forming process may be selectively performed. In the present exemplary embodiment, the surface 21a of the first conductivity-type semiconductor layer 21 exposed after the removal of the growth substrate 10 is modified, and then, the current spreading layer 44 is formed on the entire modified surface 21a. However, it is understood that one or more other exemplary embodiments are not limited thereto and either of the surface modifying process or the current spreading layer forming process may be omitted or both may be omitted.

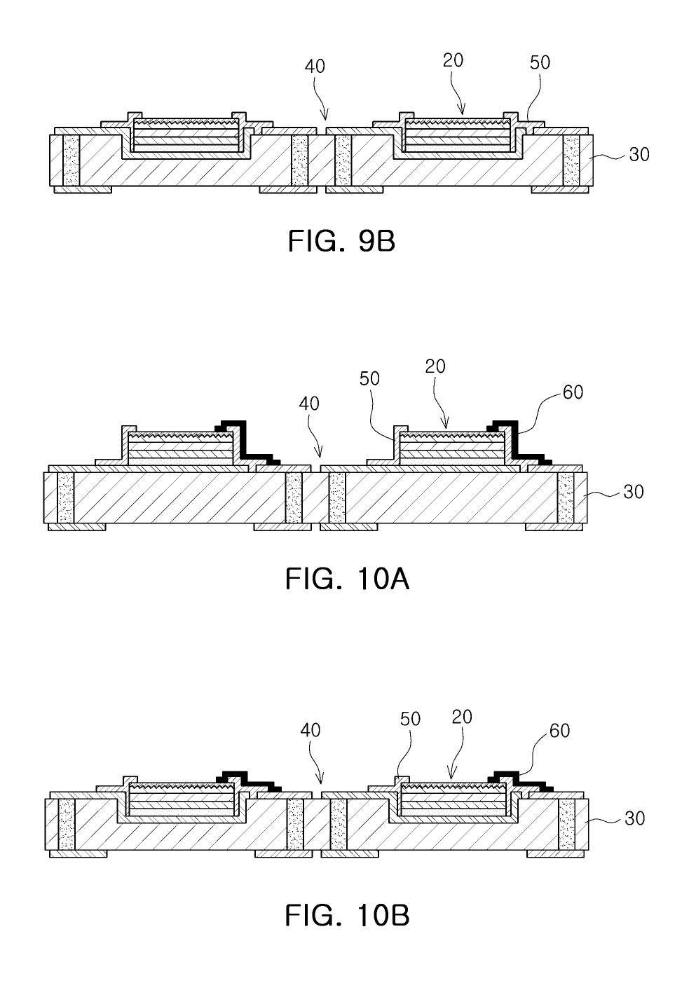

Then, as illustrated in FIG. 9A, an insulating layer 50 is formed on the lateral surface of the plurality of light emitting laminates 20. The insulating layer 50 may protect the lateral surfaces exposed from the light emitting laminate 20 and prevent a problem in which the first conductivity-type semiconductor layer 21 and the second conductivity-type semiconductor layer 23 are electrically connected to cause a short. Also, the insulating layer 50 may electrically insulate the first electrode terminal 41 and the second electrode terminal 42 provided on the substrate 30.

Meanwhile, as illustrated in FIG. 9B, when the recess 31 is formed on the substrate 30, the insulating layer 50 fills a gap between the light emitting laminate 20 and the first electrode terminal 41 formed within the recess 31 and, at the same time, insulates the first conductivity-type semiconductor layer 21 and the second conductivity-type semiconductor layer 23 exposed from the sides, from the first electrode terminal 41. Also, the insulating layer 50 may electrically insulate the first electrode terminal 41 and the second electrode terminal 42 provided on the substrate 30.

Then, as illustrated in FIGS. 10A and 10B, the exposed first conductivity-type semiconductor layer 21 is electrically connected to a different electrode terminal, i.e., the second electrode terminal 42, of the corresponding terminal unit 40. In detail, a circuit wiring layer 60 is patterned to be formed on the insulating layer 50 insulating the first electrode terminal 41 and the second electrode terminal 42 on the substrate 30 to electrically connect the first conductivity-type semiconductor layer 21 to the second electrode terminal 42.

Thus, the second conductivity-type semiconductor layer 23 of the light emitting laminate 20 is electrically connected to the first electrode terminal 41 and the first conductivity-type semiconductor layer 21 thereof is electrically connected to the second electrode terminal 42, thus making an electrical conduction.

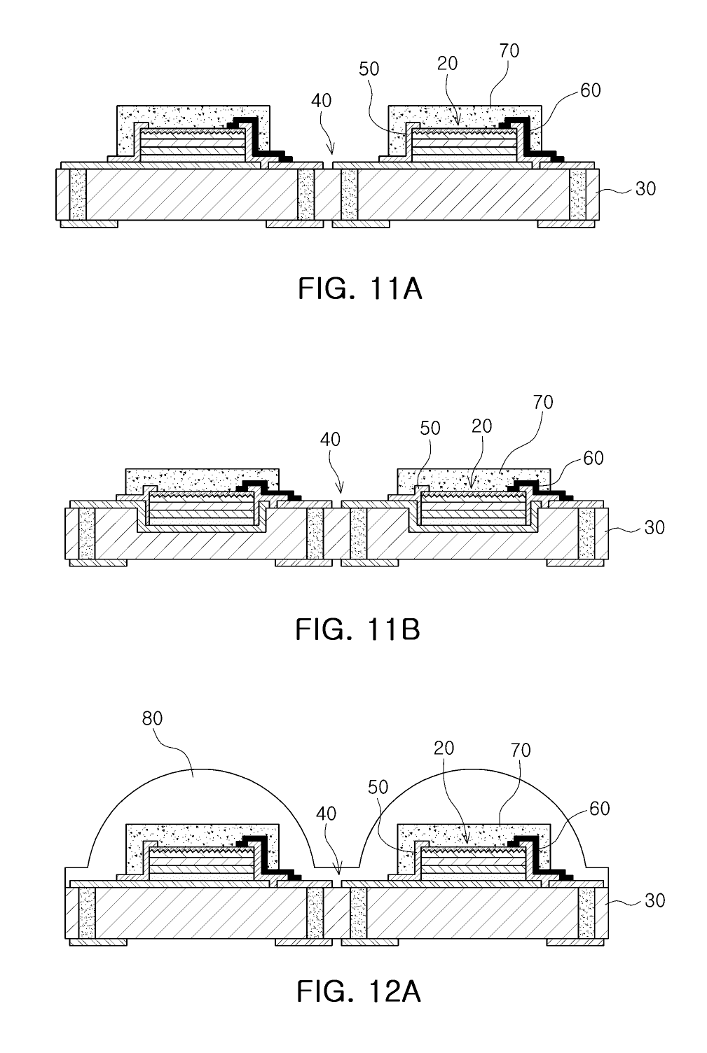

Meanwhile, as illustrated in FIGS. 11A and 11B, a wavelength conversion layer 70 may be formed on the substrate 30 to cover the light emitting laminate 20. The wavelength conversion layer 70 may convert a wavelength of light output from the light emitting laminate 20 into a wavelength of light having a desired color. For example, the wavelength conversion layer 70 is able to convert monochromatic light such as red light or blue light into white light. A resin used to form the wavelength conversion layer 70 may contain one or more types of phosphor materials. Also, the resin of the wavelength conversion layer 70 may contain a UV ray absorbent absorbing UV light generated from the light emitting laminate 20.

As an example, the wavelength conversion layer 70 may be made of a resin having a high level of transparency allowing light generated from the light emitting laminate 20 to pass therethrough with a minimal amount of loss. For example, the wavelength conversion layer 70 may be made of an elastic resin. Such an elastic resin is a gel-type resin such as silicon, or the like, which is rarely changed by light having a short wavelength, resulting in yellowing and a high refractive index, having excellent optical characteristics.

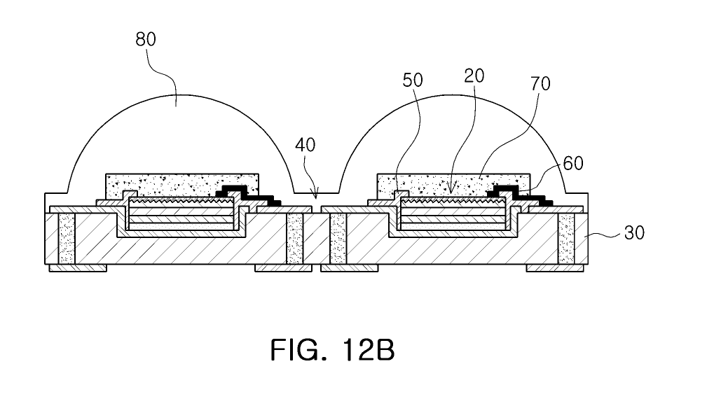

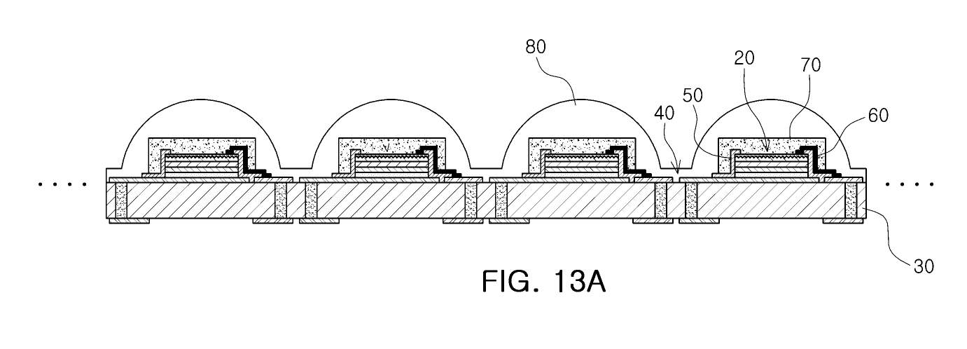

Then, as illustrated in FIGS. 12A and 12B, a molded unit 80 may be formed to cover the light emitting laminate 20 on the substrate 30. The molded unit 80 covers the light emitting laminate 20, the wavelength conversion layer 70, and the terminal unit 40 provided on the substrate 30 to protect the light emitting laminate 20, the wavelength conversion layer 70, and the terminal unit 40 from the outer environment. The molded unit 80 may be formed to have a lens shape protruded upwardly on each of the light emitting laminates 20. Accordingly, light extraction efficiency of light output from the respective light emitting laminates 20 can be increased and an angle of beam spreading can be adjusted.

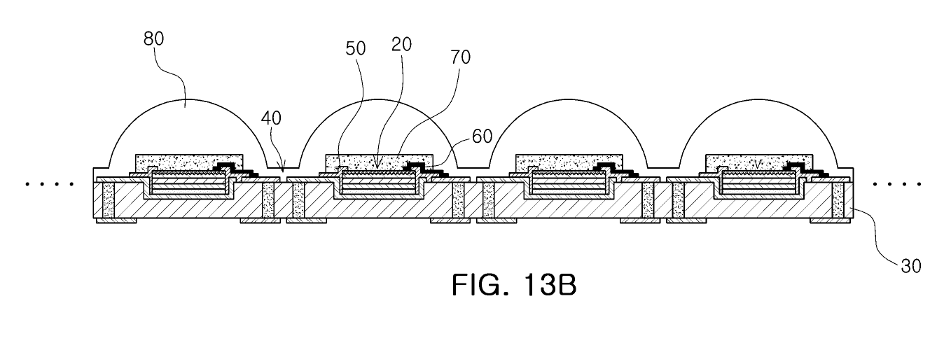

Thereafter, as illustrated in FIGS. 13A and 13B, the plurality of light emitting laminates 20 are severed to be separated, thus fabricating the light emitting device 1.

FIGS. 14A and 14B are views schematically showing the light emitting device 1 fabricated through the foregoing method. Since the plurality of light emitting laminates 20 are severed in a state of being arranged on the substrate 30, the severed sections of the substrate 30 and the molded unit 80 exposed from the lateral surfaces of each light emitting device 1 may be coplanar.

As illustrated, the light emitting laminate 20 may be directly mounted on the substrate 30 without a support substrate supporting the light emitting laminate 20. Thus, since the light emitting laminate 20 is directly mounted on the upper surface of the substrate 30, omitting a support substrate to be mounted on the substrate 30, the number of components is reduced, and the light emitting device 1 is reduced in thickness, obtaining an effect in which the size of the product is reduced. Furthermore, when the recess 31 is formed in the substrate 30 as illustrated in FIG. 14B, since the light emitting laminate 20 is accommodated in the recess 31, the height of the light emitting device 1 is further lowered, maximizing the reduction level of the light emitting device 1.

In addition, rather than employing a scheme in which the light emitting laminate 20 is diced on the growth substrate 10 and then individually mounted, the plurality of light emitting laminates 20 are collectively bonded to the substrate 30 on a wafer level, so the process can be simplified and mass-production can be facilitated, thereby enhancing productivity.

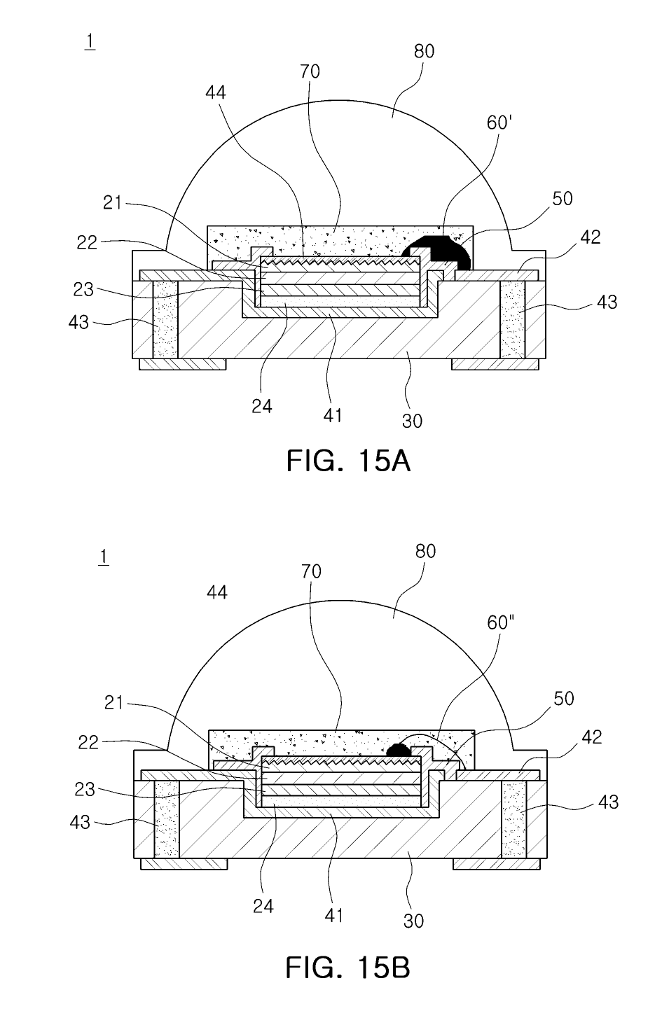

FIGS. 15A and 15B are views schematically showing a modification of a light emitting device 1 fabricated according to an exemplary embodiment. As illustrated in FIG. 15A, the first conductivity-type semiconductor layer 21 and the second electrode terminal 42 may be electrically connected through a metal stud bump 60′. Also, as illustrated in FIG. 15B, the first conductivity-type semiconductor layer 21 and the second electrode terminal 42 may be electrically connected through wire 60″ bonding.

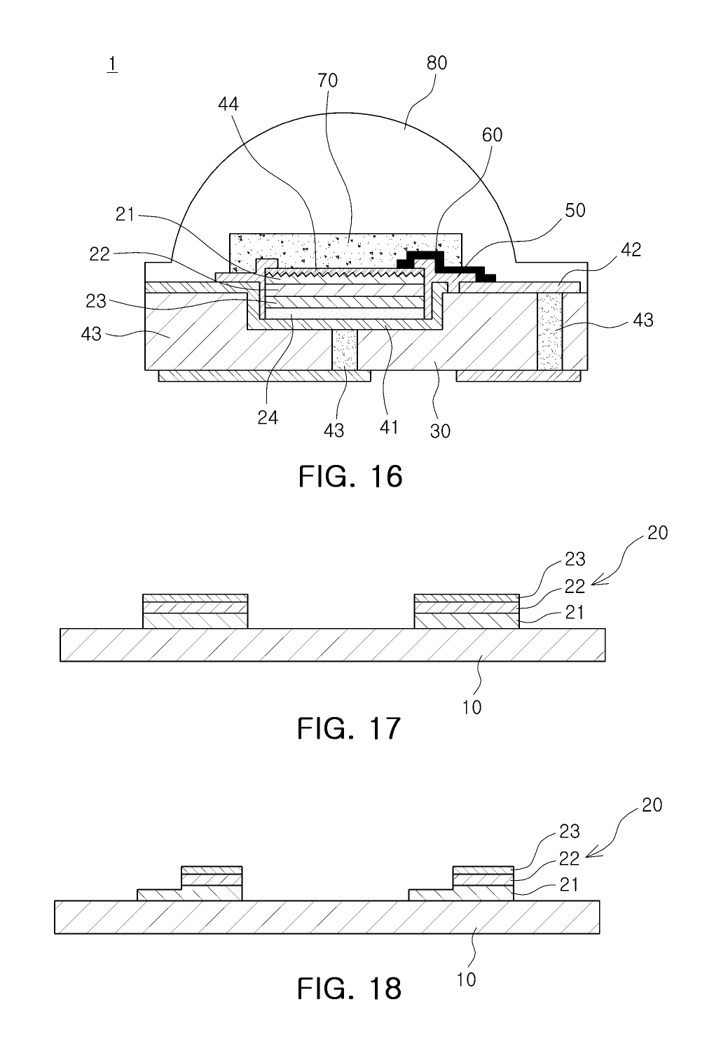

FIG. 16 is a view schematically showing another modification of a light emitting device 1 fabricated according to an exemplary embodiment. As illustrated in FIG. 16, a portion of the conductive via 43 connected to the electrode terminal 41 to which the light emitting laminate 20 is joined may be positioned under the light emitting laminate 20. Thus, heat generated from the light emitting laminate 20 may be quickly transmitted downwardly through the conductive via 43 so as to be dissipated to the outside, obtaining an effect of enhancing heat dissipation efficiency.

A method of fabricating a light emitting device 1 according to another exemplary embodiment will be described with reference to FIGS. 17 through 20. FIGS. 17 through 20 are views schematically illustrating respective steps of a method of fabricating a light emitting device 1 according to another exemplary embodiment.

As illustrated in FIG. 17, a plurality of light emitting laminates 20 on which the first conductivity-type semiconductor layer 21, the active layer 22, and the second conductivity-type semiconductor layer 23 are sequentially laminated are formed on the growth substrate 10. A specific process of forming the light emitting laminate 20 is substantially the same as or similar to the process described above with reference to FIGS. 1 through 3, so a description thereof will be omitted herein.

Next, as illustrated in FIG. 18, portions of the second conductivity-type semiconductor layer 23 and the active layer 22 of each of the light emitting laminates 20 are removed to expose a portion of the first conductivity-type semiconductor layer 21. Here, the portions of the second conductivity-type semiconductor layer 23 and the active layer 22 may be removed through mesa etching, and the first conductivity-type semiconductor layer 21 may be exposed from the removed region.

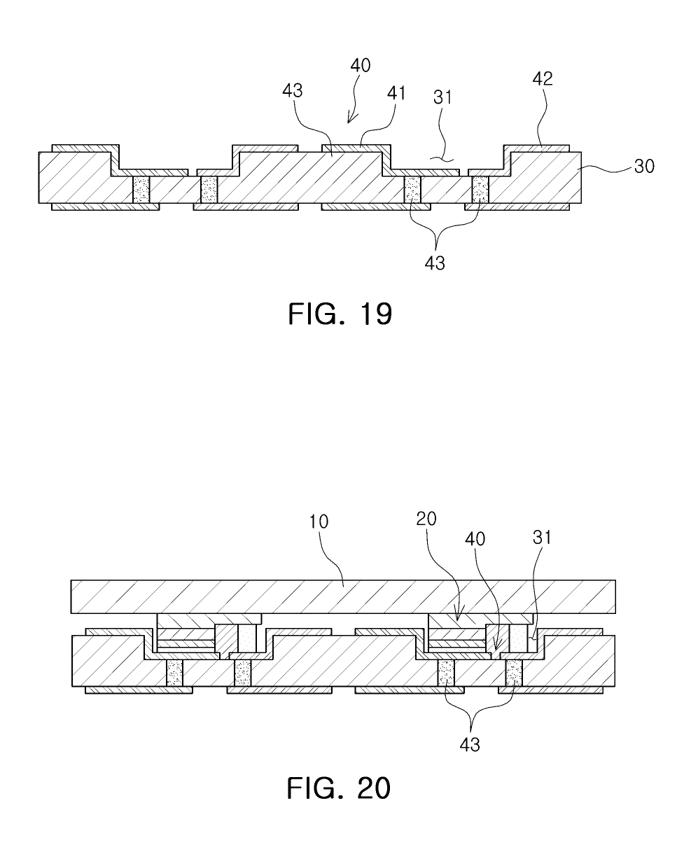

Then, as shown in FIG. 19, a substrate 30 on which a plurality of terminal units 40 including a pair of first electrode 41 and second electrode 42 are provided is prepared. The substrate 30 may further include the recess 31 for accommodating the light emitting laminate 20. In the present exemplary embodiment, the substrate 30 includes the recess 31, although it is understood that one or more other exemplary embodiments are not limited thereto. Namely, the substrate 30 may not have the recess 31, as shown in FIG. 4A. Hereinafter, the structure in which the substrate 30 includes the recess 31 will be described.

Portions of the pair of electrode terminals 41 and 42 of the terminal unit 40 may be formed within the recess 31. In detail, the first electrode terminal 41 and the second electrode terminal 42 may be formed on the upper surface of the substrate 30 and within the recess 31 and opposite to each other on a bottom surface of the recess 31.

Thereafter, as shown in FIG. 20, the growth substrate 10 is reversed to be disposed above the substrate 30 such that the respective light emitting laminates 20 face the respective terminal units 40 on the substrate 30. Accordingly, the growth substrate 10 is placed on the substrate 30 such that the respective light emitting laminates 20 are insertedly accommodated within the recesses 31.

Then, the second conductivity-type semiconductor layer 23 and the first conductivity-type semiconductor layer 21 of the respective light emitting laminates 20 are joined and electrically connected to the first electrode terminal 41 and the second electrode terminal 42, respectively, of the corresponding terminal units 40 formed within the recesses 31. For example, the second conductivity-type semiconductor layer 23 is joined to the first electrode terminal 41 formed on a bottom surface of the recess 31, and the first conductivity-type semiconductor layer 21 is joined to the second electrode terminal 42 formed on the bottom surface of the recess 31.

The light emitting laminate 20 may be joined and electrically connected to the first electrode terminal 41 and the second electrode terminal 42 by the electroconductive adhesive 24 provided on the second conductivity-type semiconductor layer 23 and the exposed first conductivity-type semiconductor layer 21. The conductive adhesive 24 may be made of an electrically conductive material. The light emitting laminate 20 and the electrode terminals 41 and 42 may be bonded through eutectic bonding, paste bonding, or the like.

Thereafter, as illustrated in FIGS. 6A-6B, 7A-7B, 8A-8B, 11A-11B, 12A-12B, and 13A-13B, the process of removing the growth substrate 10 to expose the first conductivity-type semiconductor layer 21, the process of modifying the surface of the exposed first conductivity-type semiconductor layer 21 or forming the current spreading layer 44, the process of forming the wavelength conversion layer 70 on the substrate 30 to cover the light emitting laminate 20, the process of forming the molded unit 80 on the substrate 30 to cover the light emitting laminate 20, and the process of cutting to separate the plurality of light emitting laminates 20, and the like, may be performed.

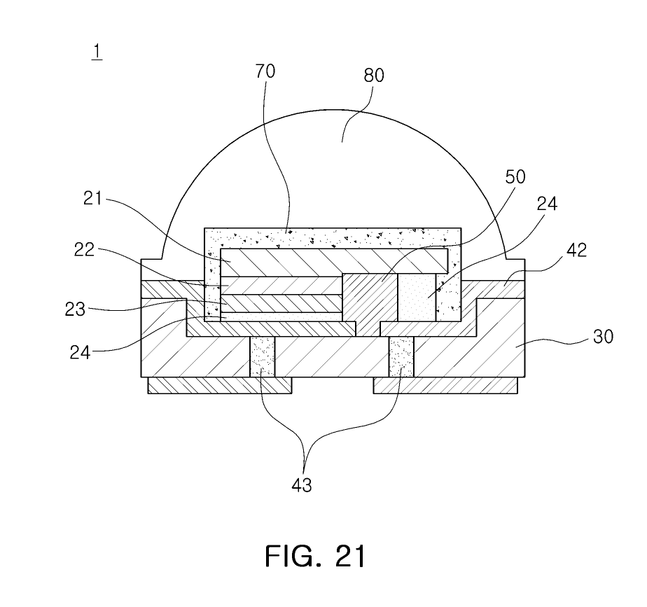

FIG. 21 is a view schematically showing a light emitting device 1 fabricated through a method of fabricating a light emitting device according to the foregoing exemplary embodiment. The light emitting device 1 has a structure in which the light emitting laminate 20 is electrically connected to the respective electrode terminals 41 and 42 through a lower surface, so light emitted upwardly is not affected, further enhancing light extraction efficiency. Namely, in the light emitting device 1 illustrated in FIG. 21, there is no influence (e.g., obstruction) on emitted light by an electrical connection between the electrode terminals 41 and 42 and the light emitting laminate 20.

As set forth above, according to exemplary embodiments, the support substrate supporting a grown semiconductor layer may be omitted in mounting the LED chip on a package substrate, so the number of components can be reduced and the fabrication process can be simplified.

While exemplary embodiments have been shown and described above, it will be apparent to those skilled in the art that modifications and variations can be made without departing from the spirit and scope of the inventive concept as defined by the appended claims.

What is claimed is:

1. A method for fabricating a light emitting device, the method comprising:
forming a plurality of light emitting laminates in which a first conductivity-type semiconductor layer, an active layer, and a second conductivity-type semiconductor layer are sequentially laminated on a growth substrate;
mounting the growth substrate on a substrate comprising a plurality of terminal units, such that the plurality of light emitting laminates respectively face the plurality of terminal units in a corresponding manner, each of the plurality of terminal units including a pair of electrode terminals;
joining and electrically connecting the second conductivity-type semiconductor layer of each of the plurality of light emitting laminates to a first electrode terminal, among the pair of electrode terminals, of a corresponding terminal unit among the plurality of terminal units;
removing the growth substrate such that the first conductivity-type semiconductor layer of each of the plurality of light emitting laminates is exposed;
forming an insulating layer on a lateral surface of each of the plurality of light emitting laminates; and
electrically connecting the exposed first conductivity-type semiconductor layer of each of the plurality of light emitting laminates to a second electrode terminal, among the pair of electrode terminals, of the corresponding terminal unit.

2. The method of claim 1, wherein the forming the plurality of light emitting laminates comprises:
sequentially growing the first conductivity-type semiconductor layer, the active layer, and the second conductivity-type semiconductor layer on the growth substrate; and
removing portions of the grown first conductivity-type semiconductor layer, the grown active layer, and the grown second conductivity-type semiconductor layer other than portions forming the plurality of light emitting laminates.

3. The method of claim 1, wherein an electroconductive adhesive is provided on the second conductivity-type semiconductor layer of each of the plurality of light emitting laminates to join the plurality of light emitting laminates and the plurality of terminal units in the corresponding manner.

4. The method of claim 1, wherein the substrate further comprises a recess which accommodates a light emitting laminate among the plurality of light emitting laminates.

5. The method of claim 4, wherein the second conductivity-type semiconductor layer is joined to the first electrode terminal within the recess.

6. The method of claim 1, further comprising:
modifying a surface of the first conductivity-type semiconductor layer after the removing of the growth substrate; and
forming a current spreading layer on the exposed first conductivity-type semiconductor layer after the removing of the growth substrate.

7. The method of claim 1, further comprising forming at least one of:
a wavelength conversion layer on the substrate to cover a light emitting laminate among the plurality of light emitting laminates; and
a molded unit on the substrate to cover the light emitting laminate.

8. The method of claim 1, further comprising cutting to separate the plurality of light emitting laminates.

9. A method for fabricating a light emitting device, the method comprising:
forming a plurality of light emitting laminates in which a first conductivity-type semiconductor layer, an active layer, and a second conductivity-type semiconductor layer are sequentially laminated on a growth substrate;
removing portions of the second conductivity-type semiconductor layer and the active layer from the plurality of light emitting laminates to expose portions of the first conductivity-type semiconductor layer;
mounting the growth substrate on a substrate comprising a plurality of terminal units, such that the plurality of light emitting laminates respectively face the plurality of terminal units in a corresponding manner, each of the plurality of terminal units including a pair of electrode terminals;
joining and electrically connecting the second conductivity-type semiconductor layer of each of the plurality of light emitting laminates to a first electrode terminal, among the pair of electrode terminals, of a corresponding terminal unit among the plurality of terminal units, and joining and electrically connecting the first conductivity-type semiconductor layer of each of the plurality of light emitting laminates to a second electrode terminal, among the pair of electrode terminals, of the corresponding terminal unit; and
removing the growth substrate such that the first conductivity-type semiconductor layer of each of the plurality of light emitting laminates is exposed.

10. The method of claim 9, wherein the forming the plurality of light emitting laminates comprises:
sequentially growing the first conductivity-type semiconductor layer, the active layer, and the second conductivity-type semiconductor layer on the growth substrate; and
removing portions of the grown first conductivity-type semiconductor layer, the grown active layer, and the grown second conductivity-type semiconductor layer other than portions forming the plurality of light emitting laminates.

11. The method of claim 9, wherein an electroconductive adhesive is provided on the second conductivity-type semiconductor layer and the exposed first conductivity-type semiconductor layer of each of the plurality of light emitting laminates to join the plurality of light emitting laminates and the plurality of terminal units in the corresponding manner.

12. The method of claim 9, wherein the substrate further comprises a recess which accommodates a light emitting laminate among the plurality of light emitting laminates.

13. The method of claim 12, wherein the second conductivity-type semiconductor layer is joined to the first electrode terminal within the recess and the exposed first conductivity-type semiconductor layer is joined to the second electrode terminal within the recess.

14. The method of claim 9, further comprising:
modifying a surface of the first conductivity-type semiconductor layer after the removing of the growth substrate; and
forming a current spreading layer on the exposed first conductivity-type semiconductor layer after the removing of the growth substrate.

15. The method of claim 9, further comprising forming at least one of:
a wavelength conversion layer on the substrate to cover a light emitting laminate among the plurality of light emitting laminates; and
a molded unit on the substrate to cover the light emitting laminate.

16. A method for fabricating a light emitting device, the method comprising:
mounting a growth substrate on a substrate comprising a plurality of terminal units, such that a plurality of light emitting laminates on the growth substrate respectively face the plurality of terminal units in a corresponding manner, wherein each of the plurality of terminal units comprise a pair of electrode terminals, and the plurality of light emitting laminates comprise a first conductivity-type semiconductor layer, an active layer, and a second conductivity-type semiconductor layer that are sequentially laminated on a growth substrate;
joining and electrically connecting the second conductivity-type semiconductor layer of each of the plurality of light emitting laminates to a first electrode terminal, among the pair of electrode terminals, of a corresponding terminal unit among the plurality of terminal units;
removing the growth substrate such that the first conductivity-type semiconductor layer of each of the plurality of light emitting laminates is exposed; and
electrically connecting the exposed first conductivity-type semiconductor layer of each of the plurality of light emitting laminates to a second electrode terminal, among the pair of electrode terminals, of the corresponding terminal unit.

17. The method of claim 16, wherein an electroconductive adhesive is provided on the second conductivity-type semiconductor layer of each of the plurality of light emitting laminates to join the plurality of light emitting laminates and the plurality of terminal units in the corresponding manner.

18. The method of claim 16, wherein the substrate further comprises a recess which accommodates a light emitting laminate among the plurality of light emitting laminates.

19. The method of claim 18, wherein the first electrode terminal is joined to the second conductivity-type semiconductor layer within the recess, and the second electrode terminal is joined to the first conductivity-type semiconductor layer outside of the recess.

20. The method of claim 18, wherein:
a portion of the first conductivity-type semiconductor layer extends beyond the second conductivity-type semiconductor layer and the active layer; and
the first electrode terminal is joined to the second conductivity-type semiconductor layer within the recess, and the second electrode terminal is joined to the first conductivity-type semiconductor layer within the recess via an adhesive.
